(19) United States
(12) Patent Application Publication
(10) Pub. No.: US 2018/0370137 A1
(43) Pub. Date: Dec. 27, 2018

(54) 3D PRINTING PEN FOR DRAWING CONDUCTIVE WIRES

(71) Applicant: HON HAI PRECISION INDUSTRY CO., LTD., New Taipei (TW)

(72) Inventors: SHUN-CHUAN YANG, New Taipei (TW); YU-CHIAO HUANG, New Taipei (TW); CHUN-PING WANG, New Taipei (TW)

(21) Appl. No.: 15/787,791

(22) Filed: Oct. 19, 2017

(30) Foreign Application Priority Data
Jun. 21, 2017 (TW) 106120800

(51) Int. Cl. B29C 64/264; B29C 64/209; B33Y 30/00; H05K 3/12

(52) U.S. Cl. CPC B29C 64/264; B29C 64/209; B29L 2031/3425; H05K 3/1275; B33Y 30/00

(57) ABSTRACT

A 3D printing pen for drawing conductive wires includes a tube, a nozzle, at least two conduits, at least one light, and a controller. The nozzle has a securing portion and a discharge portion. The securing portion is attached to the tube. The discharge portion is mounted on the securing portion. The conduits are disposed in the tube. Each conduit has a lower portion extending into the securing portion and the discharge portion of the nozzle. Different light curable materials are contained in each conduit. The light is mounted on the securing portion of the nozzle. The controller has a power unit disposed in the tube. The power unit causes the light curable materials to flow from the discharge portion of the nozzle, the light irradiates and cures the light curable materials to form a conductive wire.

### CROSS REFERENCE TO RELATED APPLICATION

This application claims priority to Taiwan Patent Application No. 106120800, filed on Jun. 21, 2017, the disclosure of which is incorporated herein by reference in its entirety.

### FIELD

The present disclosure relates to a three-dimensional (3D) printing pen for drawing conductive wires.

### BACKGROUND

A conventional 3D printing pen allows a 3D object to be drawn in space. However, the conventional 3D printing pen cannot draw a conductive wire. The conventional 3D printing pen cannot be used in maintenance operations for printed circuit boards such as connecting two nodes on a printed circuit board.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a schematic front view of a 3D printing pen.

FIG. 2 is a schematic front view in partial section of the 3D printing pen of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

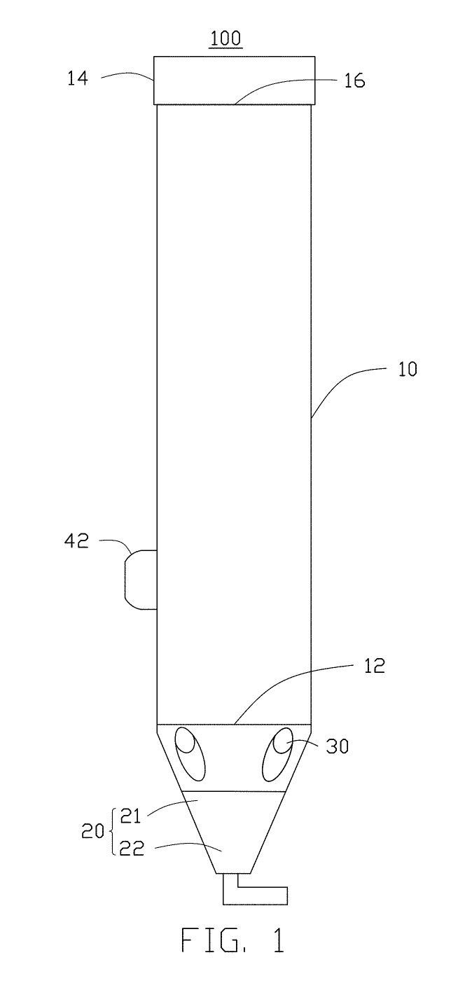

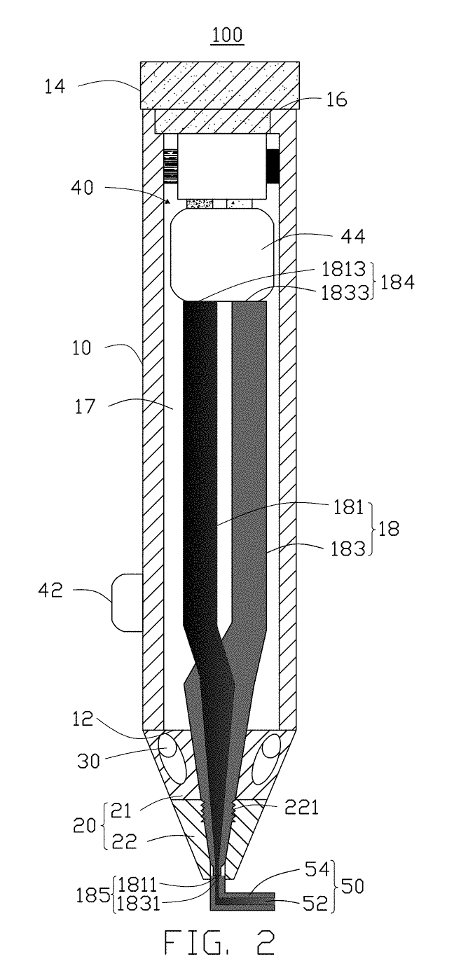

With reference to FIGS. 1 and 2, an exemplary embodiment of a 3D printing pen 100 includes a tube 10, a nozzle 20, a cover 14, at least two conduits 18, at least one light 30, and a controller 40. The tube 10 has an open upper end 16, an open lower end 12, and a chamber 17. The nozzle 20 has a securing portion 21 and a discharge portion 22. The securing portion 21 is attached to the open lower end 12 of the tube 10. The discharge portion 22 is detachably mounted on the securing portion 21. The cover 14 is detachably mounted on the open upper end 16 of the tube 10. The conduits 18 are disposed in the chamber 17 of the tube 10. Each conduit 18 has an inlet 184, an outlet 185, and a lower portion. The inlet 184 of each conduit 18 is adjacent to the open upper end 16 of the tube 10. The lower portion of each conduit 18 extends into the securing portion 21 and the discharge portion 22 of the nozzle 20 such that the outlet 185 of each conduit 18 is disposed in the discharge portion 22 of the nozzle 20. Different light curable materials are contained in each conduit 18. The light 30 is mounted on the securing portion 21 of the nozzle 20. The controller 40 has a power unit 44 and a switch 42. The power unit 44 is disposed in the chamber 17 of the tube 10, is attached to the cover 14, and covers the inlets 184 of the conduits 18. The switch 42 is located outside the tube 10. A user can actuate the power unit 44 and generate a pushing force to cause the light curable materials to flow from the discharge portion 22 of the nozzle 20 and actuate the light 30 to irradiate and cure the light curable materials from the discharge portion 22 of the nozzle 20, thereby forming a conductive wire 50. The power unit 44 may be a mechanical power unit, a pneumatic power unit, or a hydraulic power unit. The power unit 44 is conventional and thus a detailed description thereof will be omitted.

A diameter of the conductive wire 50 is determined by an inner diameter of the discharge portion 22 of the nozzle 20. The discharge portion 22 is detachably mounted to the securing portion 21 by a connecting structure 221. The connecting structure 221 may be a threaded structure or a press-fit structure. The connecting structure 221, as shown in FIG. 2, is the threaded structure. Other discharge portions 22 having different inner diameters can be mounted to the securing portion 21 such that the diameter of the conductive wire 50 can be changed quickly and efficiently. The connecting structure 221 is conventional and thus a detailed description thereof will be omitted.

In the present exemplary embodiment, the conduits 18 include a first conduit 181 and a second conduit 183. The first conduit 181 and the second conduit 183 are parallel to each other in the chamber 17 of the tube 10. The first conduit 181 has a lower portion extending inside a lower portion of the second conduit 183. The first conduit 181 has a first inlet 1813 and a first outlet 1811, and the second conduit 183 has a second inlet 1833 and a second outlet 1831. The first outlet 1811 is surrounded by the second outlet 1831, and the second outlet 1831 is surrounded by the discharge portion 22 of the nozzle 20. A first light curable material 52 is contained in the first conduit 181, and a second light curable material 54 is contained in the second conduit 183. The first light curable material 52 has silver ions and is conductive. The second light curable material 54 is lipophilic and insulating and is non-conductive. The first light curable material 52 and the second light curable material 54 are incompatible with each other. The second light curable material 54 flowing from the second outlet 1831 of the second conduit 183 covers the first light curable material 52 flowing from the first outlet 1811 of the first conduit 181 to form the conductive wire 50.

In the present exemplary embodiment, two lights 30 are mounted on the securing portion 21 of the nozzle 20 to uniformly irradiate the first light curable material 52 and the second light curable material 54.

In other exemplary embodiments, the power unit 44 is mounted in the cover 14. The power unit 44 moves away from and opens the inlets 184 of the conduits 18 when the cover 14 is detached from the tube 10. The open inlets 184 allow the light curable materials to infill the conduits 18.

The exemplary embodiments shown and described above are only examples. Many details are often found in the art such as the other features of a 3D printing pen. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the exemplary embodiments described above may be modified within the scope of the claims.

What is claimed is:

1. A three-dimensional (3D) printing pen comprising:
a tube having an open lower end and a chamber;
a nozzle having:
a securing portion attached to the open lower end of the tube; and
a discharge portion mounted on the securing portion;
at least two conduits disposed in the chamber of the tube, and each conduit having a lower portion extending into the securing portion and the discharge portion of the nozzle;
at least one light mounted on the securing portion of the nozzle; and
a controller having a power unit disposed in the chamber of the tube;
wherein a different light curable material is contained in each conduit; and
wherein the power unit causes the light curable materials to flow from the discharge portion of the nozzle, and the light irradiates and cures the light curable materials, thereby forming a conductive wire.

2. The 3D printing pen of claim 1, further comprising a cover mounted on an open upper end of the tube;
wherein the power unit is attached to the cover, and generates a pushing force to cause the light curable materials to flow from the discharge portion of the nozzle.

3. The 3D printing pen of claim 1, wherein the conduits comprise a first conduit and a second conduit, the first conduit and the second conduit are parallel to each other in the tube, and the first conduit has a lower portion extending inside a lower portion of the second conduit.

4. The 3D printing pen of claim 2, wherein the conduits comprise a first conduit and a second conduit, the first conduit and the second conduit are parallel to each other in the tube, and the first conduit has a lower portion extending inside a lower portion of the second conduit.

5. The 3D printing pen of claim 3, wherein the first conduit has a first outlet surrounded by a second outlet of the second conduit, and a second light curable material flowing from the second outlet of the second conduit covers a first light curable material flowing from the first outlet of the first conduit.

6. The 3D printing pen of claim 4, wherein the first conduit has a first outlet surrounded by a second outlet of the second conduit, and a second light curable material flowing from the second outlet of the second conduit covers a first light curable material flowing from the first outlet of the first conduit.

7. The 3D printing pen of claim 5, wherein the second outlet of the second conduit is surrounded by the discharge portion of the nozzle.

8. The 3D printing pen of claim 6, wherein the second outlet of the second conduit is surrounded by the discharge portion of the nozzle.

9. The 3D printing pen of claim 7, wherein the discharge portion is detachably mounted to the securing portion by a connecting structure.

10. The 3D printing pen of claim 8, wherein the discharge portion is detachably mounted to the securing portion by a connecting structure.

11. The 3D printing pen of claim 5, wherein the first light curable material is conductive, the second light curable material is non-conductive, and the first light curable material and the second light curable material are incompatible with each other.

12. The 3D printing pen of claim 6, wherein the first light curable material is conductive, the second light curable material is non-conductive, and the first light curable material and the second light curable material are incompatible with each other.

13. The 3D printing pen of claim 7, wherein the first light curable material is conductive, the second light curable material is non-conductive, and the first light curable material and the second light curable material are incompatible with each other.

14. The 3D printing pen of claim 8, wherein the first light curable material is conductive, the second light curable material is non-conductive, and the first light curable material and the second light curable material are incompatible with each other.

15. The 3D printing pen of claim 9, wherein the first light curable material is conductive, the second light curable material is non-conductive, and the first light curable material and the second light curable material are incompatible with each other.

16. The 3D printing pen of claim 10, wherein the first light curable material is conductive, the second light curable material is non-conductive, and the first light curable material and the second light curable material are incompatible with each other.

17. The 3D printing pen of claim 11, wherein the first light curable material comprises silver ions, and the second light curable material is lipophilic.

18. The 3D printing pen of claim 12, wherein the first light curable material comprises silver ions, and the second light curable material is lipophilic.

19. The 3D printing pen of claim 13, wherein the first light curable material comprises silver ions, and the second light curable material is lipophilic.

20. The 3D printing pen of claim 14, wherein the first light curable material comprises silver ions, and the second light curable material is lipophilic.
